(19) United States
(12) Patent Application Publication
(10) Pub. No.: US 2014/0329459 A1
(43) Pub. Date: Nov. 6, 2014

(54) Multipurpose Pad for Mobile Devices

(71) Applicants: Craig Salathe, Redmond, WA (US); Jesse Rapczak, Kirkland, WA (US)

(72) Inventors: Craig Salathe, Redmond, WA (US); Jesse Rapczak, Kirkland, WA (US)

(21) Appl. No.: 13/888,332

(22) Filed: May 6, 2013

(51) Int. Cl. H05K 7/02; H04B 7/155

(52) U.S. Cl. CPC H05K 7/02; H04B 7/155
USPC 455/11.1; 361/679.01

(57) ABSTRACT

A Multipurpose Pad for Mobile Devices may allow mobile devices to be used for multiple purposes at business establishments. A Multipurpose Pad for Mobile Devices may comprise a durable mat cut the shape of a mobile device and containing a base with plurality of gripping feet. It may also comprise a charging station that facilitates the transmission of near field communication (NFC), Wi-Fi, Bluetooth, FM, or other signals with the mobile device, or permit the user to receive advertisements, submit orders, transact payments, or engage in other communications with the business establishment.

### FIELD

This disclosure relates to a Multipurpose Pad for Mobile Devices.

### BACKGROUND

Mobile devices, for example, smartphones and tablets, have become ubiquitous in modern society. Consumers often bring personal mobile devices into business establishments such as shops, restaurants and bars. However, businesses typically lack clean designated surfaces on which customers could place and use their devices while awaiting or receiving service. For example, bar patrons risk their smartphones getting sticky upon resting them on countertops.

While many establishments provide coasters, trays or mats for beverages or food dishes, these platforms are not tailored to the shapes and functions of mobile devices.

### SUMMARY

The following presents a simplified summary of the disclosure in order to provide a basic understanding to the reader. This summary is not an extensive overview of the disclosure and does not identify key or critical elements of the subject matter, nor does it define the scope of the claimed subject matter. Its sole purpose is to present some concepts disclosed in a simplified form as a prelude to the more detailed description that is presented later.

The instant application discloses, among other things, a Multipurpose Pad for Mobile Devices, which may allow mobile devices to be used for multiple purposes at business establishments. In one embodiment, it may comprise a textured mat with gripping feet, cut in the shape of a mobile device. In another embodiment, it may comprise an electronic terminal that provides inductive charging for mobile devices. In yet another embodiment, it may allow software on the mobile device to receive advertising, and in another embodiment, it may utilize near field communication (NFC) technology to permit payment transactions on the mobile device.

A Multipurpose Pad for Mobile Devices, with an appropriate infrastructure, may provide an integrated platform for providing services including, for example, wireless charging, Wi-Fi access, social networking, discount coupons, loyalty programs, social games, information services, ordering, and paying.

Many of the attendant features may be more readily appreciated as they become better understood by reference to the following detailed description considered in connection with the appended drawings.

### BRIEF DESCRIPTION OF THE DRAWINGS

The present description may be better understood from the following detailed description read in light of the accompanying drawings, wherein:

FIG. 1 is a system that may support a Multipurpose Pad for Mobile Devices according to one embodiment.

FIG. 2 is a top perspective view of a Multipurpose Pad for Mobile Devices with gripping feet, cut in the shape of a mobile device, according to one embodiment.

FIG. 3 is a perspective view of a Multipurpose Pad for Mobile Devices with gripping feet, cut in the general shape of a mobile device, according to one embodiment.

FIG. 4 is an example of another embodiment of a Multipurpose Pad for Mobile Devices.

FIG. 5 illustrates a restaurant using Multipurpose Pad for Mobile Devices according to one embodiment.

FIG. 6 illustrates a component diagram of a computing device according to one embodiment.

### DETAILED DESCRIPTION

The detailed description set forth below in connection with the accompanying drawings is intended as a description of example embodiments of a Multipurpose Pad for Mobile Devices and is not intended to represent the only forms in which the embodiments may be constructed or used.

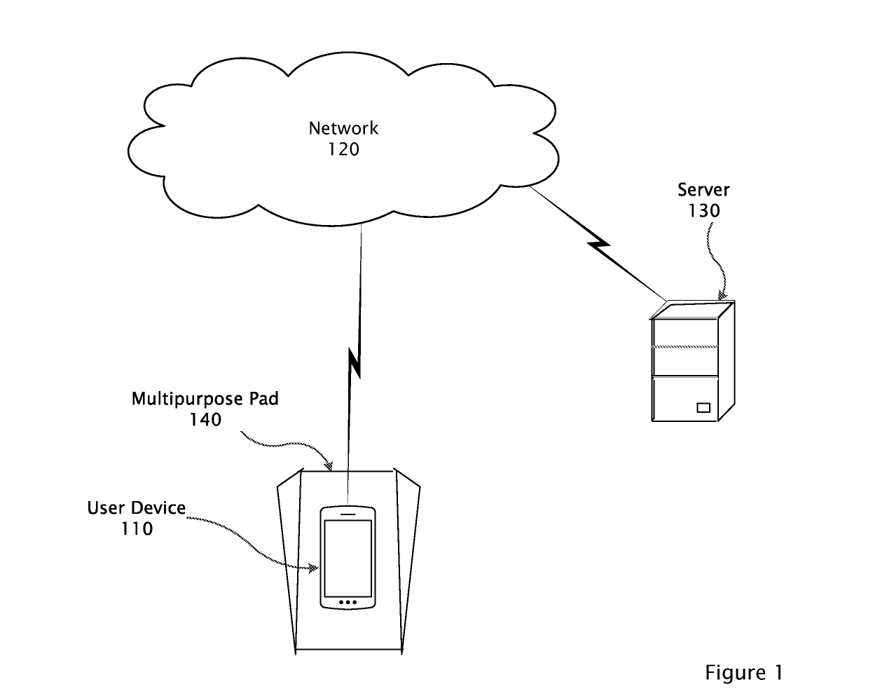

FIG. 1 is a system that may support a Multipurpose Pad for Mobile Devices 140 according to one embodiment. User Device 110 may be a smartphone, a tablet computer, a laptop, or any other device capable of executing software and including a location awareness technology, such as a GPS, cellphone tower triangulation ability, or accelerometers to track movement. User Device 110 may execute a dedicated application for using Multipurpose Pad 140, may access a web site, may require placing a phone call, sending a text message, or may provide similar functionality through other means. User Device 110 may send identification and location information to Server 130 via Network 120 through services offered by Multipurpose Pad 140.

Multipurpose Pad 140 may provide access to Network 120 for User Device 110 by virtue of communications between Multipurpose Pad 140 and User Device 110. For example, Multipurpose Pad 140 may support near field communications (NFC) and may provide information to User Device 110.

In one embodiment, Multipurpose Pad 140 may be at a section in a business; a table or an area of a bar in a restaurant, for example. User Device 110 may connect with Multipurpose Pad 140 and, by virtue of that connection, have access to Network 120, which may provide software or content that may be of interest to a user. For example, ads or discounts on food or drinks may be served to User Device 110. A user may be able to order food or drinks, or pay a bill through User Device 110, with the restaurant knowing which table or user based on which Multipurpose Pad 140 is associated with User Device 140. Content and services may include receiving advertisements, discount offers, menus, nutritional information, requesting table service, communicating with a coat check service, weather, accommodation information, transportation information games, social networking, videos, music, printing a file, transferring files to a remote storage location, checking on parking garage vacancies, triggering a lock on a bike rack, monitoring a parking meter, refilling a parking meter, and checking on restroom availability.

A business providing a Multipurpose Pad for Mobile Device 140 may require a user to view an ad, check in, complete a survey, pay a fee, or perform some other act to access a benefit such as wireless charging, and may have different requirements for different benefits. Such a business may also have different embodiments of a Multipurpose Pad for Mobile Device for users who desire differing levels of service.

Network 120 may include Wi-Fi, cellular data access methods, such as 3G or 4GLTE, Bluetooth, NFC, the internet, local area networks, wide area networks, or any combination of these or other means of providing data transfer capabilities. In one embodiment, Network 120 may comprise Ethernet connectivity.

Server 130 may include one or more computers, and may serve a number of roles. Server 130 may be conventionally constructed, or may be of a special purpose design for processing data obtained from User Device 110. One skilled in the art will recognize that Server 130 may be of many different designs and may have different capabilities.

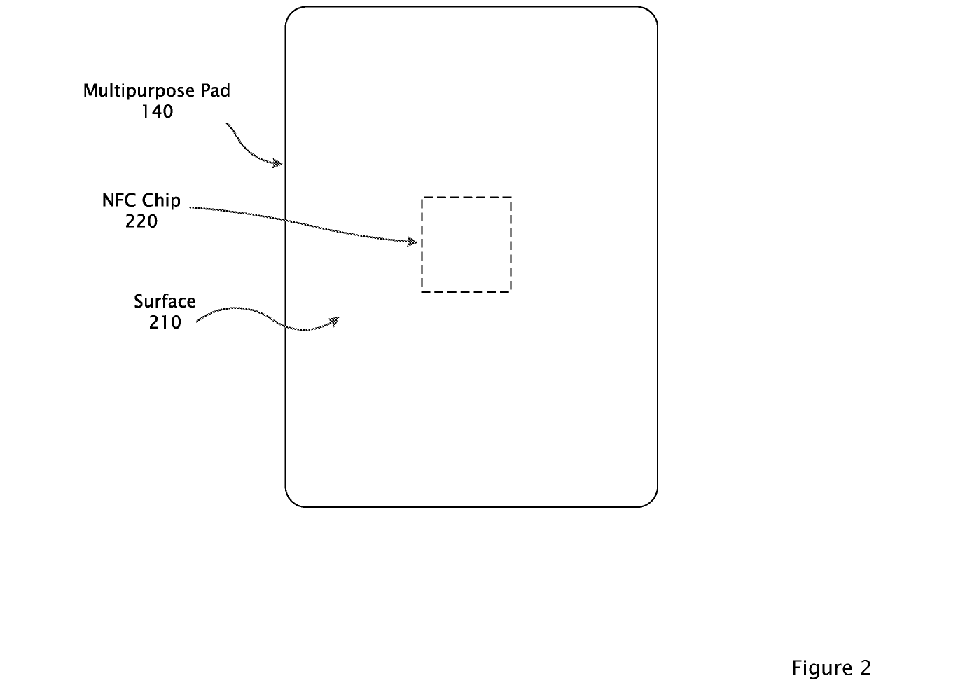

FIG. 2 is a top perspective view of a Multipurpose Pad for Mobile Devices with gripping feet, cut in the shape of a mobile device, according to one embodiment. Top Surface 210 may be constructed out of a durable material such as rubber, plastic, wood, metal, or carbon fiber and may be cut in the shape of a mobile device. One having skill in the art will recognize that a pad may be made of various materials, and that a pad may be made into various shapes.

Near field communications (NFC) Chip 220 may be used to identify which of a plurality of Multipurpose Pads for Mobile Devices 140 is being accessed.

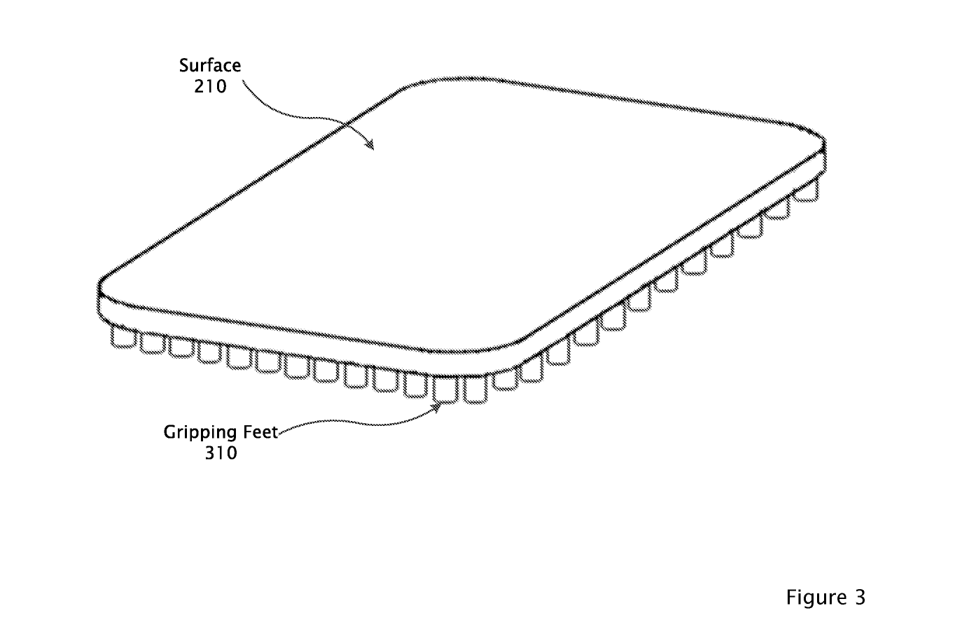

FIG. 3 is a perspective view of a Multipurpose Pad for Mobile Devices 140 with gripping feet, cut in the general shape of a mobile device, according to one embodiment. In this embodiment, the bottom of the pad may contain a plurality of Gripping Feet 310 that may provide traction when the pad is placed on a surface such as a countertop or table. Surface 210 may hold a mobile device above a plane of a table, which may provide some protection for the mobile device against materials on the table. For example, if the table is sticky from previously spilled beer, the textured mat may help keep the mobile device clean.

A Multipurpose Pad for Mobile Devices 140 may include a transceiver or similar technology, which may allow a mobile device placed on or near it access to special software or data. For example, a mobile phone placed on Surface 210 may be used to order food or drink from a bar. A system may recognize the Multipurpose Pad for Mobile Devices 140 associated with the mobile phone, and may be able to route the order to the appropriate staff to fulfill and delivery the order. In another embodiment, software may be enabled to allow a user to pay a bill, with a system recognizing which user is paying. One having skill in the art will recognize that many other features may be enabled.

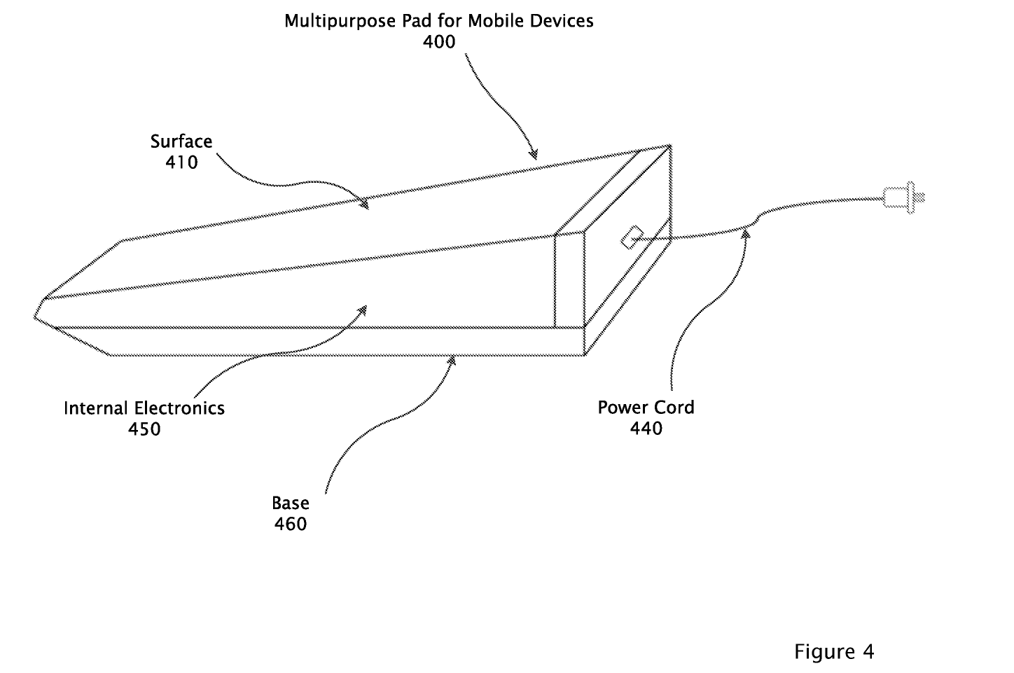

FIG. 4 is an example of another embodiment of a Multipurpose Pad for Mobile Devices 400. This embodiment may contain a top Surface 410 on which a mobile device may be placed. It may also include an interior cavity containing Electronics 450 and other devices, for example, near field communication (NFC) transceivers, readers, chips, or coils. It may also contain a Base 460 and an Electrical Power Cord 440. This embodiment may allow software on the coupled mobile device to receive advertising and may utilize NFC technology to permit payment transactions or allow communications between the user and business establishment on the mobile device.

In one embodiment, Internal Electronics 450 may provide inductive charging for a mobile device placed on or near Surface 410. Multipurpose Pad for Mobile Devices 140 may be associated with a particular location at a bar, or a particular table. In another embodiment a mobile device placed on or near Surface 410 may receive or view advertisements, discount offers, menus, or other information pertaining to a business establishment, its sponsors or other parties. For example, a restaurant may offer a discount on a pitcher of pop to go with an order of food for a particular table, while offering an appetizer special to another table where drinks were ordered.

In yet another embodiment, of a Multipurpose Pad for Mobile Devices 140 may allow for playing games, participate in social networking, or provide other forms of entertainment on a mobile device.

In yet another embodiment, a Multipurpose Pad for Mobile Devices 140 may communicate with business establishment's coat check system, which may allow a client to request retrieval of an article prior to getting to the coat check.

In yet another embodiment, a Multipurpose Pad for Mobile Devices 140 may enable a user to receive information regarding parking garage vacancies, trigger a lock on a bike rack, or monitor or refill a parking meter. In yet another embodiment, a Multipurpose Pad for Mobile Devices 140 may serve as a mobile device stand or tripod which allows user to take photos or videos from a distance.

In yet another embodiment, a Multipurpose Pad for Mobile Devices 140 may permit a user to communicate with a home management system, a work surveillance system, or another type of system which may be remotely accessed. In yet another embodiment, a Multipurpose Pad for Mobile Devices 140 may allow user to view restroom availability. In yet another embodiment, a Multipurpose Pad for Mobile Devices 140 may be configured to provide a Breathalyzer or other tests. In yet another embodiment, a Multipurpose Pad for Mobile Devices 140 may receive, transmit, or utilize solar power.

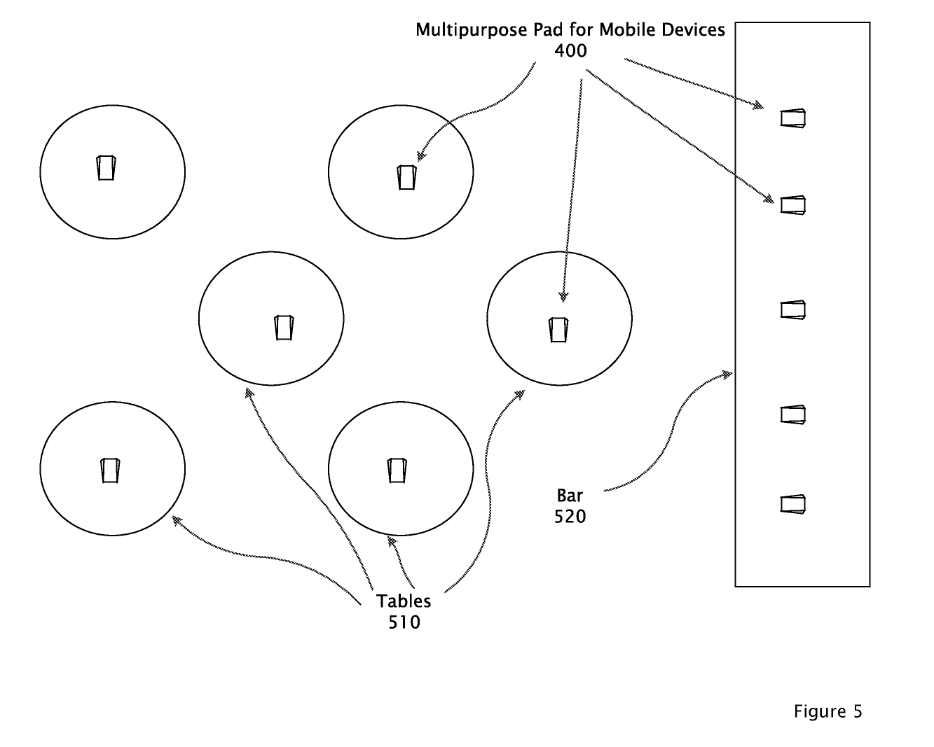

FIG. 5 illustrates a restaurant using Multipurpose Pad for Mobile Devices according to one embodiment. A restaurant may have several Tables 510 and may deploy a Multipurpose Pad for Mobile Device 400 on each one. Several Multipurpose Pad for Mobile Devices may be deployed on Bar 520. A client may place a smartphone on a Multipurpose Pad for Mobile Device 400, and a connection may be established between the two devices using near field communications or another means. This may allow the restaurant to know where the client is sitting, for example which Table 510 or which seat at the Bar 520. The restaurant may then allow access to various capabilities, for example, wireless charging, Wi-Fi access, social networking, discount coupons, loyalty programs, social games, information services, ordering, and paying.

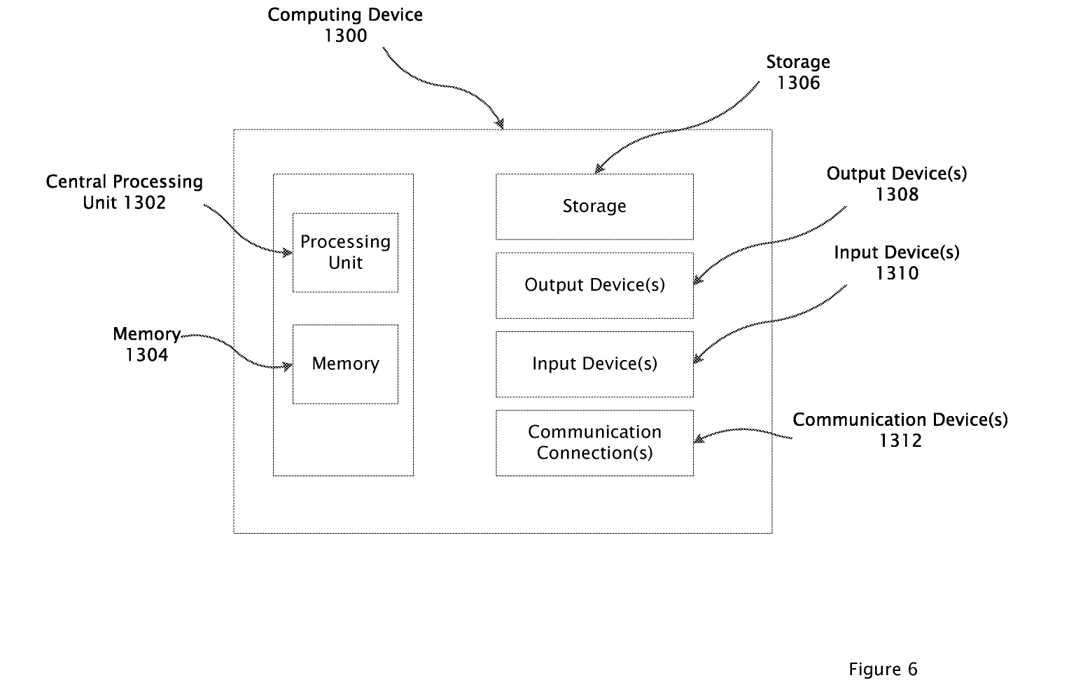

FIG. 6 illustrates a component diagram of a computing device according to one embodiment. The computing device (1300) can be utilized to implement one or more computing devices, computer processes, or software modules described herein. In one example, the computing device (1300) can be utilized to process calculations, execute instructions, receive and transmit digital signals. In another example, the computing device (1300) can be utilized to process calculations, execute instructions, receive and transmit digital signals, receive and transmit search queries, and hypertext, compile computer code as required by a Server 130, User Device 110, or Multipurpose Pad for Mobile Devices 140. The computing device (1300) can be any general or special purpose computer now known or to become known capable of performing the steps and/or performing the functions described herein, either in software, hardware, firmware, or a combination thereof.

In its most basic configuration, computing device (1300) typically includes at least one central processing unit (CPU) (1302) and memory (1304). Depending on the exact configuration and type of computing device, memory (1304) may be volatile (such as RAM), non-volatile (such as ROM, flash memory, etc.) or some combination of the two. Additionally, computing device (1300) may also have additional features/functionality. For example, computing device (1300) may include multiple CPU's. The described methods may be executed in any manner by any processing unit in computing device (1300). For example, the described process may be executed by both multiple CPU's in parallel.

Computing device (1300) may also include additional storage (removable and/or non-removable) including, but not limited to, magnetic or optical disks or tape. Such additional storage is illustrated in FIG. 8 by storage (1306). Computer readable storage media includes volatile and nonvolatile, removable and non-removable media implemented in any method or technology for storage of information such as computer readable instructions, data structures, program modules or other data. Memory (1304) and storage (1306) are all examples of computer storage media. Computer readable storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can accessed by computing device (1300). Computer readable storage media does not include transient signals. Any such computer readable storage media may be part of computing device (1300).

Computing device (1300) may also contain communications device(s) (1312) that allow the device to communicate with other devices. Communications device(s) (1312) is an example of communication media. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. The term computer-readable media as used herein includes both computer storage media and communication media. The described methods may be encoded in any computer-readable media in any form, such as data, computer-executable instructions, and the like.

Computing device (1300) may also have input device(s) (1310) such as keyboard, mouse, pen, voice input device, touch input device, etc. Output device(s) (1308) such as a display, speakers, printer, etc. may also be included. All these devices are well known in the art and need not be discussed at length.

Those skilled in the art will realize that storage devices utilized to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network). Those skilled in the art will also realize that by utilizing conventional techniques known to those skilled in the art that all, or a portion of the software instructions may be carried out by a dedicated circuit, such as a DSP, programmable logic array, or the like.

While the detailed description above has been expressed in terms of specific examples, those skilled in the art will appreciate that many other configurations could be used. Accordingly, it will be appreciated that various equivalent modifications of the above-described embodiments may be made without departing from the spirit and scope of the invention.

Additionally, the illustrated operations in the description show certain events occurring in a certain order. In alternative embodiments, certain operations may be performed in a different order, modified or removed. Moreover, steps may be added to the above described logic and still conform to the described embodiments. Further, operations described herein may occur sequentially or certain operations may be processed in parallel. Yet further, operations may be performed by a single processing unit or by distributed processing units.

The foregoing description of various embodiments of the invention has been presented for the purposes of illustration and description. It is not intended to be exhaustive or to limit the invention to the precise form disclosed. The above specification, examples and data provide a complete description of the manufacture and use of the invention.

1. A pad comprising:
a mat, comprising:
a top surface, the top surface sized to hold a mobile device; and
a base, comprising a plurality of gripping feet; and
a near field communication chip, the near field communication chip identifying a location.

2. The pad of claim 1, wherein the location identifies a section in a business; the section selected from the group comprising a table and an area of a bar.

3. A pad, comprising:
a case, comprising:
a top surface;
a base;
a plurality of sides connecting the top surface to the base, the sides, top surface, and base forming a waterproof enclosure; and
a location identifying means enclosed within the waterproof enclosure, the location identifying means coupled to a device external to the case.

4. The pad of claim 3, further comprising a wireless charging system within the enclosure, configured to inductively charge the device.

5. The pad of claim 3, wherein the top surface is configured to hold the device, the top surface having an anti-slip coating.

6. The pad of claim 3, further comprising a communication means, the communication means configured to communicate with the device.

7. The pad of claim 6 wherein the communication means is selected from a group containing near field communication, Wi-Fi, Bluetooth, and RFID.

8. A system, comprising:
a pad configured to communicate with a mobile device and a computer, the computer comprising:
a processor;
memory, coupled to the processor; and
a computer readable storage medium, containing software and content, the content available to the mobile device via the pad.

9. The system of claim 8, wherein the content comprises content selected from a group containing advertisements, discount offers, and menus.

10. The system of claim 8 wherein the content comprises a means for performing an action selected from a group containing: making a payment, placing an order, receive nutritional information, requesting table service, communicate with a coat check service, play a game, participate in social networking, watch a video, listen to music, print a file, and transfer files to a remote storage location.

11. The system of claim 8 wherein the content comprises a means for viewing information about a topic selected from a group containing: weather, transportation, and accommodations.

12. The system of claim 8 wherein the content comprises a means for performing an action selected from a group containing: check on parking garage vacancies, trigger a lock on a bike rack, monitor a parking meter, and refill a parking meter.

13. The system of claim 8 wherein the content comprises a means for checking on restroom availability.
